(19) United States
(12) Patent Application Publication
(10) Pub. No.: US 2011/0210428 A1
(43) Pub. Date: Sep. 1, 2011

(54) METHOD FOR PRODUCING A SEMICONDUCTOR COMPONENT, SEMICONDUCTOR COMPONENT AND INTERMEDIATE PRODUCT IN THE PRODUCTION THEREOF

(76) Inventors: Bernd Bitnar, Freiberg (DE); Holger Neuhaus, Freiberg (DE); Andreas Krause, Dresden (DE)

(21) Appl. No.: 12/673,244

(22) PCT Filed: Aug. 12, 2008
(86) PCT No.: PCT/EP2008/006624

§ 371 Date: Feb. 12, 2010

(30) Foreign Application Priority Data
Aug. 16, 2007 (DE) 10 2007 038 744.1

(51) Int. Cl. H01L 21/02; H01L 21/28; H01L 23/48

(52) U.S. Cl. 257/632; 438/597; 257/734; 257/E21.158; 257/E21.002; 257/E23.01

(57) ABSTRACT

Method for producing semiconductor components with a contact structure having a high aspect ratio comprising the following steps: providing an essentially plane semiconductor substrate having a first side and a second side, applying a mask onto at least a first partial area on at least one of the sides of the semiconductor substrate and applying a contact structure onto at least a second partial area, which is different from first partial area, on at least one of the sides of semiconductor substrate.

### CROSS REFERENCE TO RELATED APPLICATIONS

This application is a United States National Phase application of International Application PCT/EP2008/006624 and claims the benefit of priority under 35 U.S.C. §119 of German patent application DE 10 2007 038 744.1 filed Aug. 16, 2007, the entire contents of which are incorporated herein by reference.

### FIELD OF THE INVENTION

The present invention pertains to a method for producing semiconductor components. The invention also relates to a semiconductor component and an intermediate product in the production of a semiconductor component.

### BACKGROUND OF THE INVENTION

A semiconductor component usually consists of a substrate having a front side and a rear side, with a contact structure applied to at least one of the two sides. Typically the contact structure has a width of at least 100 μm, while its thickness is only about 10 to 15 μm. A greater width of the contact structure leads to a reduction of the efficiency owing to the increased shading, while a reduction of the width entails the disadvantage that the line resistance of the contact structure is increased.

### SUMMARY OF THE INVENTION

The invention is therefore based on the object of creating a favorably priced method for producing a contact structure with a high aspect ratio AV and a semiconductor component with a contact structure of such kind

Said object is achieved by a method for producing semiconductor components comprising the steps of providing an essentially plane semiconductor substrate having a first side and a second side lying opposite thereto, applying a mask onto at least a first partial area on at least one of the sides of the semiconductor substrate and applying a contact structure with a height H onto at least a second partial area on at least one of the sides of the semiconductor substrate. Said object is further achieved by a method in which the mask is made of an organic material, especially of an epoxy resin and/or at least in part of wax. Said object is furthermore achieved by a method in which the mask is made of a non-wetting material. The core of the invention consists in providing the semiconductor substrate with a mask, especially printing on it, prior to the application of the contact structure. The mask is essentially a negative image of the desired contact structure, i.e. it is exclusively applied onto the semiconductor substrate areas not to be metallized. The mask advantageously has a thickness which is at least as great as that of the contact structure to be applied. The flanks of the apertures in the mask are preferably designed to be steep, which leads to an advantageous geometry, especially to a high aspect ratio, of the contact structure.

The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

In the drawings:

FIG. 1 is a schematic cross-sectional view through a semiconductor component with an applied mask;

FIG. 2 is a cross-sectional view through the semiconductor component according to FIG. 1 after a process step in which apertures were made in an intermediate layer between the semiconductor substrate and the mask;

FIG. 3 is a cross-sectional view through the semiconductor component according to FIG. 2 after the application of a multi-layer contact structure; and

FIG. 4 is a cross-sectional view through the semiconductor component according to FIG. 3 after removal of the mask.

### DESCRIPTION OF THE PREFERRED EMBODIMENTS

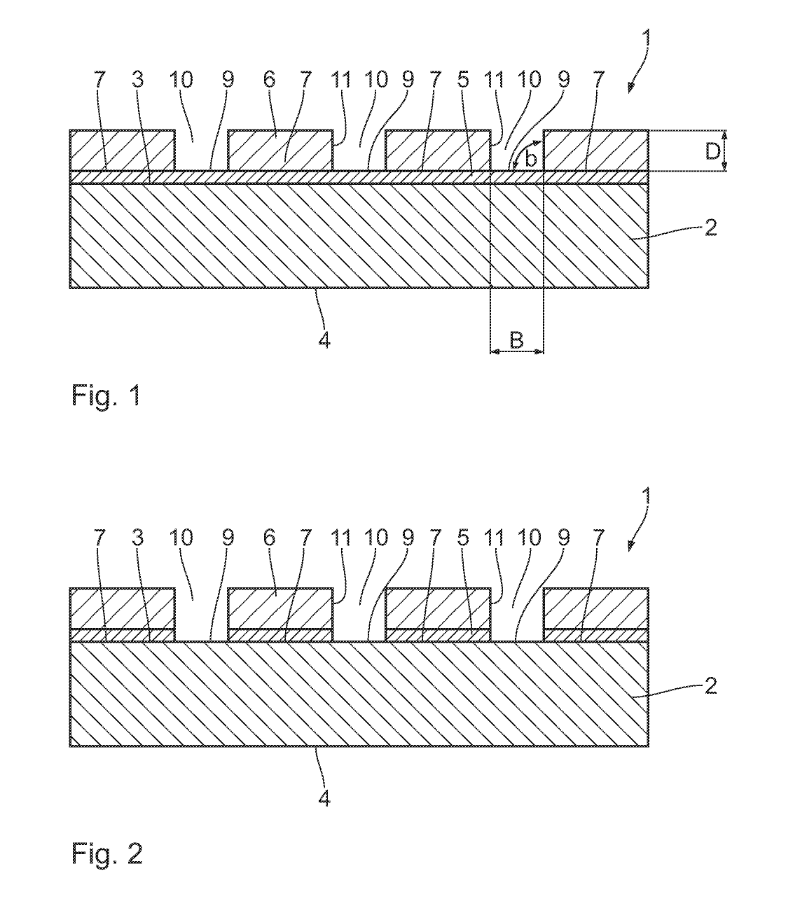

In the following there is described with reference to FIGS. 1 to 4 a semiconductor component according to the present invention. As a starting point there is a semiconductor component 1 which exhibits a substrate 2. The substrate 2 consists at least partly of silicon. Especially a silicon substrate serves as the substrate 2. However, another semiconductor substrate may also serve as the substrate 2 in the same way. The substrate 2 is essentially of a planar design having a first side and a second side lying opposite thereto, the first side forming a front side 3, while the second side forms a rear side 4 of the substrate 2.

In the following there is described with reference to FIG. 1 a first intermediate product in the production of the semiconductor component 1. On the front side 3 of the substrate 2 there is applied an intermediate layer 5 as a passivation layer. The intermediate layer 5 consists, for example, of silicon nitride or silicon dioxide. The intermediate layer 5 is designed as an anti-reflection layer. The intermediate layer 5 can also be applied on the rear side 4 of the substrate 2.

On the intermediate layer 5 there is applied, at least in parts, a mask 6. The mask 6 is made of an organic material, typically of an epoxy resin such as epichlorohydrin or bisphenol A or of polymethylmethacrylate (PMMA). It can also at least in part be made of a hot-melt wax. It can also be formed of other materials. The mask 6 is preferably made of a material, which, with regard to the solutions envisaged for the production of a contact structure 8, is non-wetting, so that they roll off from the mask 6. In other words the contact angle formed between said solutions and the mask 6 is at least 90°. Moreover, the mask 6 is resistant to the solutions envisaged for the production of the contact structure 8, especially etch-resistant to hydrofluoric acid and/or fluoride-containing pastes. Moreover, the mask 6 is preferably made of a heat-resistant material. Moreover, it is especially made of a light-resistant material, i.e. it does not change its properties during irradiation with light. The mask 6 is applied on a first partial area 7 on the front side 3 of the substrate 2, in which no contact structures 8 are envisaged. In areas, in which contact structures 8 are envisaged, the mask 6 exhibits apertures 10. The apertures 10 are especially designed in a channel-like way. The apertures 10 have a width B in the range of 10 μm to 200 μm, especially in the range of 30 μm to 100 μm. The mask 6 has a thickness D in the range of 1 μm to 50 μm.

On the sides the mask 6 is confined by the flanks 11 facing the apertures 10, which flanks extend to the intermediate layer 5. The flanks 11 are designed to be steep, i.e. they make an angle b with the front side 3 of the substrate 2, or with the intermediate layer 5, to which angle the following applies: 70°≦b≦100°, especially 80°≦b≦90°. The apertures 10 are thus confined by the flanks 11 of the mask 6, while their floor is formed by the intermediate layer 5.

In a subsequent production stage the apertures 10 extend to the substrate 2, as shown in FIG. 2, i.e. in this stage the floor of the apertures 10 is formed by the substrate 2. The flanks 11 of the mask 6 continue, especially flush, through to the front side 3 of the substrate 2. Especially the width B of the apertures 10 in the area of the intermediate layer 5 is at least almost the same as the width B of the apertures 10 in the area of the mask 6.

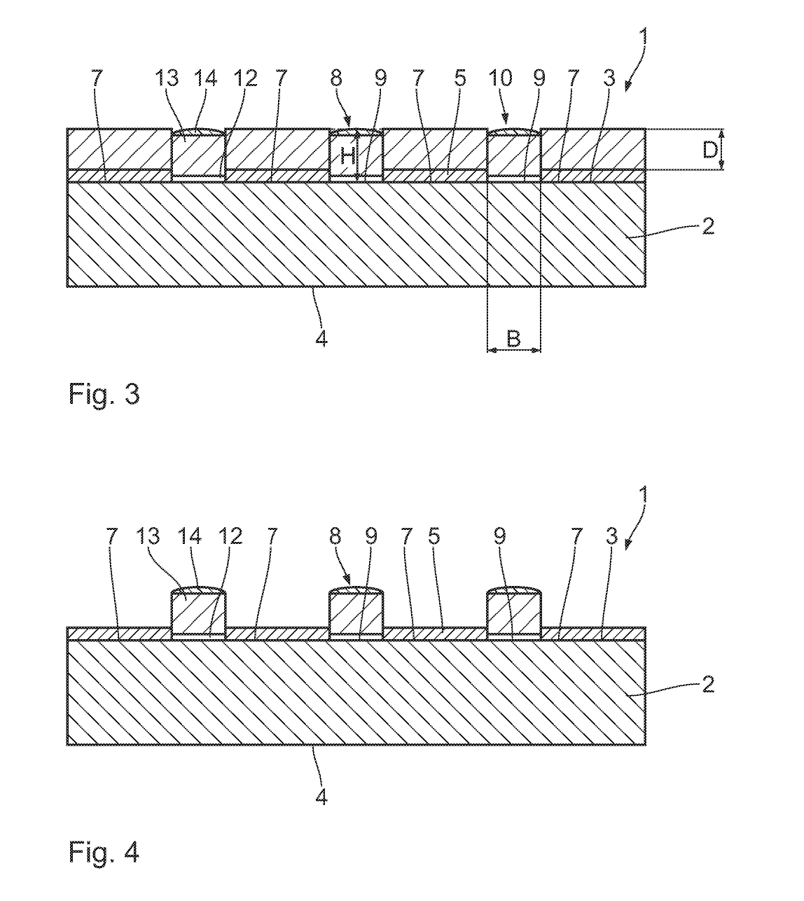

In the following there is described with reference to FIG. 3 another intermediate product during the production of the semiconductor component 1. After a further process step the semiconductor component 1 exhibits the contact structure 8. The contact structure 8 is arranged in the apertures 10 of the mask 6, i.e. in a second partial area 9 on the front side 3 of the substrate 2. The first partial area 7 and the second partial area 9 are especially complementary towards each other, i.e. they are overlap-free and their unification covers the entire front side 3 of the substrate 2. The contact structure 8 is thus confined on the sides by the flanks 11. It thus has the same width B as the apertures 10. The height H of the contact structure 8 is advantageously smaller than the sum of the thickness D of the mask 6 and the layer thickness of the intermediate layer 5. The thickness D of the mask 6 is especially at least as great as the height H of the contact structure 8. The height H of the contact structure 8 is more than 10 μm, especially more than 30 μm. The contact structure 8 thus has a high aspect ratio AV, which is determined as the ratio of the height H of the contact structure 8 to its width B, which is just as great as the width B of the apertures 10, AV=H/B. The aspect ratio AV of the contact structure 8 is at least 0.1, especially at least 0.3, especially at least 0.5.

The contact structure 8 has a multi-layer design. It comprises a barrier layer 12, which is arranged on the substrate 2 and in contact therewith, a conductor layer 13, which is arranged on the barrier layer 12, and a cover layer 14, which is arranged on the conductor layer 13. The thickness of the barrier layer 12 is 0.1 to 5 μm, especially 0.2 to 1 μm. The barrier layer 12 is made of a material, especially a metal, which has a negligible diffusion coefficient or a negligible mixability with regard to the material of the substrate 2 and the conductor layer 13. The barrier layer 12 is made of an electrolytically or chemically applied nickel, cobalt or a nickel-cobalt alloy. Other materials are also conceivable. The barrier layer 12 advantageously has a high electrical conductivity. Advantageously, the material of the barrier layer 12 can be stripped well electromechanically. This applies in particular to cobalt.

The conductor layer 13 is made of copper. It exhibits a high electrical conductivity. The conductor layer 13 can also at least in part be made of another material with a high electrical conductivity. It is especially possible that the conductor layer 13 contains at least some silver. The conductor layer 13 is especially made of a material, which exhibits a very small partial diffusion coefficient with regard to the material of the barrier layer 12. Advantageously, there exists between the material 12 on the one hand and the material of the conductor layer 13 on the other hand only a very low mixability.

On the conductor layer 13 there is arranged the cover layer 14. The cover layer 14 is especially made of tin. It may also be made of silver and/or nickel. The cover layer 14 is corrosion-protective.

While the barrier layer 12 and the conductor layer 13 are, on their side facing away from the substrate 2, designed essentially flat and parallel with the front side 3 of the substrate 2, the cover layer 14 is designed to be slightly convex. The thickness of the cover layer 14 thus decreases a little towards the fringe area on the side of the contact structure 8, as a result of which the contact structure 8 exhibits rounded-off outer edges on its outer side facing away from the substrate 2.

The contact structure 8 can also exhibit another number of layers. It can especially be made of e.g. silver in a single-layer design. The contact structure 8 exhibits a line resistance of less than 40 Ω/m, especially less than 20 Ω/m, especially less than 10 Ω/m.

The arrangements of the intermediate layer 5, the mask 6 and the contact structure 8 are not restricted to the front side 3 of the substrate 2 but may also be envisaged in the same way on the rear side 4.

In the following there is described with reference to FIG. 4 the completed semiconductor component 1. After another process step, in which the mask 6 was removed, the contact structure 8 on the substrate 2 is largely exposed. It is only is surrounded on the sides by the intermediate layer 5 up to layer thickness thereof.

In the following there is described the method for producing the semiconductor component 1. First, the substrate 2 with the intermediate layer 5 is made available and provided with the mask 6. The mask 6 is applied by means of printing method, especially by means of an ink jet printing method, i.e. an inkjet method, or by means of a screen-printing method or generally a digital printing method. Alternatively, the mask 6 can also be applied by means of a dispersion or extrusion coating method. Through methods of this kind, the layout of the mask 6 is selectable and realizable in an especially easy, flexible and precise manner.

In a subsequent process step the intermediate layer 5 is removed in the area of the apertures 10 of the mask 6. For this, especially an etching process, for example by means of hydrofluoric acid, fluoride-containing pastes or by means of plasma etching is employed, the mask 6 being resistant to the etching chemicals used.

Thereafter, in another process step, a first chemical or electrolytic precipitation, the barrier layer 12 is applied onto the substrate 2 in the area of the apertures 10. In the case of galvanic precipitation, a seed layer may first be precipitated through chemical treatment in a palladium solution. Good adhesion of the barrier layer 12 on the substrate 2 is achieved, especially for a galvanic coating. For the electrolytic precipitation of the barrier layer 12 there are especially envisaged Watt's baths, which exhibit a moderately acidic pH value, especially pH 3 to 5. Other baths with a pH value in excess of pH 3 may also be used. The electric potential for the electrolytic precipitation of the barrier layer 12 can be generated by irradiation of the substrate 2 with light of a suitable wavelength and intensity. Moreover, the electrical resistance of the substrate 2 can be reduced though this measure. When the substrate 2 is removed from the bath, the solution rolls off from the mask 6 because of the non-wetting property thereof, so that mixing, especially the contamination of a subsequent bath, is reduced.

In a further process step, a second chemical or electrolytic precipitation, the conductor layer 13 is applied onto the barrier layer 12. To this end, the semiconductor component 1 is immersed in an acidic copper bath in a potential-controlled manner, i.e. the potential is already applied before the semiconductor component is immersed in the bath. The electrolytic precipitation can be supported by irradiation with light of a suitable wavelength and intensity.

In another process step the cover layer 14 is applied onto the conductor layer 13. To this end, the semiconductor component 1 is briefly immersed in a silver bath. Alternatively, the cover layer 14 can also be applied in a more economic way by means of electrolytic precipitation of tin and/or nickel. Thus, only galvanic or chemical processes are employed for the production of the contact structure 8.

The contact structure 8 produced according to the present invention exhibits stable layers. Pull-off tests have shown a very good adhesive strength of the contact structure 8 on the silicon substrate 2. Since the flanks 11 of the mask 6 prevent the contact structure 8 from becoming broader, a contact structure 8 with a high aspect ratio AV is producible through the method according to the present invention. The thickness D of the mask 6 is especially selected such that the contact structure 8 does not grow beyond the mask 6.

In a further process step, the mask 6 is removed. To this end, a chemical process, especially an etching process, in a solvent such as acetone or an alkaline solution is envisaged. A plasma etching process may also be applied.

In a variant of the method, the mask 6 is removed after the application of the conductor layer 13. The cover layer 14 is applied after the removal of the mask 6, thereby encompassing the conductor layer 13 on three sides.

In order to reduce the transfer resistance between the contact structure 8 and the substrate 2 through the formation of a metal semiconductor alloy, a temper process is applied after the production of the contact structure.

While specific embodiments of the invention have been shown and described in detail to illustrate the application of the principles of the invention, it will be understood that the invention may be embodied otherwise without departing from such principles.

1. A method for producing semiconductor components, the method comprising the following steps:
providing an essentially plane semiconductor substrate having a first side and a second side lying opposite thereto;
applying a mask onto at least a first partial area on at least one of the sides of the semiconductor substrate;
applying a contact structure with a height H onto at least a second partial area on at least one of the sides of the semiconductor substrate.

2. A method according to claim 1, wherein the partial areas are complementary towards each other.

3. A method according to claim 1, wherein the mask is applied onto the substrate by means of a printing method.

4. A method according to claim 1, wherein the mask comprises a thickness D, which is at least as great as the height H of the contact structure.

5. A method according to claim 1, wherein the mask comprises apertures, which exhibit a width B in the range of 10 μm to 200 μm.

6. A method according to claim 5, wherein the mask comprises flanks, which are arranged to make an angle b with the first side of the substrate, to which angle the following applies: 70°≦b≦100°.

7. A method according to claim 1, wherein the contact structure comprises a height H and a width B, and an aspect ratio AV, which equals the ratio of the height H to the width B, AV=H/B, the aspect ratio AV being at least 0.1.

8. A method according to claim 1, wherein the mask is made of an etch-resistant material.

9. A method according to claim 1, wherein the mask is made of a heat-resistant material.

10. A method according to claim 1, wherein the mask is made of an organic material.

11. A method according to claim 1, wherein the mask is made of a non-wetting material.

12. A method according to claim 1, wherein the contact structure comprises several layers.

13. An intermediate product during the production of a semiconductor component according to claim 1, the product comprising:
a semiconductor substrate of an essentially planar design having a first side and a second side lying opposite thereto; and
a mask applied at least in areas on at least one of the sides of the semiconductor substrate.

14. A semiconductor component comprising:
a semiconductor substrate having a first side and a second side lying opposite thereto; and
a contact structure applied onto at least one of the sides of the semiconductor substrate.

15. A method according to claim 1, wherein the mask is applied onto the substrate by means of inkjet printing.

16. A method according to claim 1, wherein the mask comprises apertures which exhibit a width B in the range of 30 μm to 100 μm.

17. A method according to claim 5, wherein the mask comprises flanks, which are arranged to make an angle b with the first side of the substrate, to which angle the following applies: 80°≦b≦90°.

18. A method according to claim 1, wherein the contact structure comprises a height H and a width B, and an aspect ratio AV, which equals the ratio of the height H to the width B, AV=H/B, the aspect ratio AV being at least 0.3.

19. A method according to claim 1, wherein the contact structure comprises a height H and a width B, and an aspect ratio AV, which equals the ratio of the height H to the width B, AV=H/B, the aspect ratio AV being at least 0.5.

20. A method according to claim 1, wherein the mask is made of at least one of the group of an epoxy resin and in part of a wax.
